(19) United States
(12) Patent Application Publication
(10) Pub. No.: US 2018/0115039 A1
(43) Pub. Date: Apr. 26, 2018

(54) HIGH POWER WAVEGUIDE CIRCULATOR WITH RADIAL BI-COMPOSITE RESONATOR

(71) Applicant: Apollo Microwaves, Ltd., Dorval (CA)

(72) Inventor: Louis-Philippe Carignan, Pincourt (CA)

(73) Assignee: Apollo Microwaves, Ltd., Dorval (CA)

(21) Appl. No.: 15/334,204

(22) Filed: Oct. 25, 2016

(51) Int. Cl. H01P 1/39; H05K 7/20

(52) U.S. Cl. CPC H01P 1/39; H05K 7/20009

(57) ABSTRACT

A waveguide circulator for use in a high power microwave circuit is provided. The circulator has three or more waveguide ports intersecting at a junction, wherein the junction has an upper inner surface and a lower inner surface positioned in an opposing relationship to said upper inner surface. The circulator further includes at least one radial bi-composite resonator positioned within the junction, the radial bi-composite resonator being comprised of a radial component including a composite made of a centrally disposed ferrite element and a solid dielectric layer disposed concentrically with and adjacent externally to said centrally disposed ferrite element and a dielectric stack covering at least in part a surface of the radial component of the radial bi-composite resonator. In use, a magnetic field source applies an external magnetic field to the radial bi-composite resonator.

### FIELD OF THE INVENTION

The present invention relates to the field of passive microwave components and, more specifically, to a space efficient configuration for a high-power waveguide circulator having one or more ferrite resonators.

### BACKGROUND

High power circulators are used in satellite communication systems and radiofrequency linear accelerators (LINACs), to protect the source from any undesired reflected power.

Waveguide circulators are known in the art for handling RF waves. Typically, waveguide circulators include three ports (although more or less ports are possible) and are used for transferring wave energy in a non-reciprocal manner, such that when wave energy is fed into one port, it is transferred in one direction to a next port only. A common use for waveguide circulators is to transmit energy from a transmitter to an antenna during transmitting operations, and to transmit energy from an antenna to a receiver during receiving operations.

In order to enable the non-reciprocal energy transfer, the waveguide circulators include ferrite resonators to which are applied a magnetic field via one or more permanent magnets or electromagnets. E-plane and H-plane waveguide circulators are two configurations of such waveguide circulators.

An example of a typical H-plane waveguide circulator 300 is illustrated in FIGS. 1A, 1B and 1C and an example of a typical E-plane waveguide circulator is illustrated in FIGS. 2A and 2B. In each of these examples, the waveguide circulator 300 (or 400) has three waveguide ports 302, 304 and 306 (or 402, 404 and 406) that meet at a common junction 308 (or 408). Shown in FIG. 1B is a side view of the waveguide circulator 300 with a view into waveguide port 306 and shown in FIG. 1C is a cut-out view of the waveguide circulator 300 with a view of the inside of junction 308. Positioned within the junction 308 of the waveguide circulator 300 is a pair of gyromagnetic members 305 and 307, which are also referred to as “ferrite resonators” and are typically made of a ferrite material. The ferrite resonators 305 and 307 are positioned within the junction 308, generally upon mounting pedestals 350 and 370 located on opposing inner surfaces 303 and 303′ of the junction 308, such that they are centrally disposed and arranged generally symmetrically, with respect to the three waveguide ports 302, 304 and 306.

Shown in FIG. 2B is a cut-out view of the waveguide circulator 400 with a view of the junction 408. Positioned within the junction 408 of the waveguide circulator 400 is a pair of gyromagnetic members 405 and 407, also referred to as “ferrite resonators” and typically made of a ferrite material. The ferrite resonators 405 and 407 are positioned within the junction 408, generally upon mounting pedestals 450 and 470 located on opposing inner surfaces 403 and 403′ of the junction 408, such that they are centrally disposed and arranged generally symmetrically, with respect to the three waveguide ports 402, 404 and 406.

During operation, the ferrite resonators 305 and 307 (or 405 and 407) are subjected to the influence of a magnetic field that is generated by one or more permanent magnets or electromagnets (not shown), which can be positioned on outside surfaces of the junction 308 (or 408) above and below the ferrite resonators 305 and 307 (or 405 and 407) to magnetize the ferrite resonators and determine a direction of circulation of the RF waves. The magnetic field that is generated is a unidirectional magnetic field, represented by arrow 309 in FIGS. 1A and 1B and by arrow 409 in FIG. 2A, such that wave energy entering each waveguide ports 302, 304 and 306 (or ports 402, 404 and 406) will move in a counter-clockwise direction (or clockwise depending on the direction of the magnetic field) towards its neighboring waveguide port in a cyclic manner. As such, the waveguide circulators 300 and 400 are non-reciprocal transmitter of electromagnetic wave energy propagating in the waveguides.

In certain applications it may be desirable to have a waveguide circuit including waveguide circulators that can handle high power RF waves, including high peak power level RF waves.

In typical systems used for high power RF waves, losses may occur due to dissipation in the ferrite resonators, which translates into heat in the ferrites. As a result, the average power of a circulator is limited by the thermal gradient over the thickness of the ferrite or, in other words, by the amount of heat that can be extracted/dissipated from the ferrites.

FIGS. 3A-B show the shape of a conventional ferrite resonator 50. In the example shown, the ferrite resonator is made entirely of a ferrite material and is of a cylindrical shape, with a diameter 2R and a thickness L. The resonator 50 would also typically sit on a metallic platform, such as platform 370 or 350 in FIG. 1B or platform 470 or 450 in FIG. 2B, which also allows some heat to be dissipated. While FIGS. 3A-B show a ferrite resonator of a cylindrical shape, it is to be appreciated that triangular and hexagonal ferrites are also used in some implementations.

In implementations of the type shown in FIGS. 3A-B, the ferrite resonator 50 is limited by the ability of the resonator 50 to transfer heat through some of its surfaces to gas that surrounds it (e.g. air. SF6, nitrogen, vacuum or any other suitable gas) and through the metallic platform on which the resonator sits.

Various alternative implementations have been proposed for improving heat extraction/dissipation from the ferrite resonators and will be described with reference to FIGS. 4A-C (resonator 52) and to FIG. 5AB (resonator 55).

One way of improving the heat transfer is to use an axial composite resonator 52, of the type shown in FIGS. 4A-C. In such a configuration, a dielectric layer 53 of thickness L_{d}=L−L_{f} and thermal conductivity σ_{d} is placed on top of a ferrite layer 54 of thickness L_{f} and having a thermal conductivity σ_{f}. When the resonator is installed in a circulator, the ferrite layer 54 typically sits on a metallic platform, such as platform 370 or 350 in FIG. 1B or platform 470 or 450 in FIG. 2B, to dissipate heat. The dielectric layer is chosen such that σ_{d}>>σ_{f}, to reduce the thermal gradient over the ferrite portion, and therefore increase the average power handling capability of the resonator 52 (compared to the configuration shown in FIGS. 3A-B). This increase in power handling capability is done at the expense of bandwidth since the bandwidth is related with the volumetric amount ferrite in the composite resonator 52. As such, implementations of resonators of the type shown in FIGS. 4A to 4C would be typically suitable for applications having relatively narrower bandwidth but higher average power requirements.

Another resonator configuration that has been proposed for improving heat transfer is a radial composite resonator 55, of the type shown in FIGS. 5A-B. In this configuration, a dielectric ring 56 of thickness L_{d}=L, with an outer diameter 2R, inner diameter 2R_{f} and thermal conductivity σ_{d} is adjacent to that of a ferrite element 57 (in this example a disk) of thickness L_{f}t=L, diameter 2R_{f} and thermal conductivity σ_{f}. When the resonator 55 is installed in a circulator, the ferrite element 57 sits on a metallic platform, such as platform 370 or 350 in FIG. 1B or platform 470 or 450 in FIG. 2B, to dissipate heat. A fraction of the heat from the ferrite element 57 is radially transferred to the dielectric ring 56. In such a configuration, the thermal gradient of the ferrite element 57 may not be decreased to the same extent as that of the ferrite layer 54 in the axial composite resonator 52 shown in FIGS. 4A-C. However, in the case of the radial composite resonator 55, the radial footprint of the ferrite element 57 is reduced (2R_{f}<2R), which in turn helps reduce the required size of the magnets needed to operate the circulator in which the radial composite resonator 55 would be used and helps improve the magnetic field uniformity within the ferrite element 55.

The person skilled in the art will appreciate that in some practical implementations, resonators 305 307 405 and 407 shown in FIGS. 1A-C and 2A-B may be embodied in the manner described with reference to resonator 50 shown in FIGS. 3A-B, to resonator 52 shown in FIGS. 4A-C and/or resonator 55 shown in FIGS. 5A-B.

While various approaches have been proposed for improving heat extraction/dissipation from the ferrite resonators, it remains desirable to find approaches that allow for greater enhanced heat dissipation of the ferrite resonators in particular when these resonators are used in high power RF wave circulators and circuits.

In light of the above, there is a need in the industry for an improved waveguide circulator that alleviates, at least in part, the deficiencies with existing waveguide circulators.

### SUMMARY

In accordance with a first aspect, a waveguide circulator for use in a high power microwave circuit is provided. The waveguide circulator comprises at least three waveguide ports intersecting at a junction, wherein the junction has an upper inner surface and a lower inner surface positioned in an opposing relationship to the upper inner surface. The waveguide circulator also comprises a radial bi-composite resonator positioned within said junction, the radial bi-composite resonator being comprised of a composite made of a radial component including a centrally disposed ferrite element and a solid dielectric layer disposed concentrically with and adjacent externally to the centrally disposed ferrite element and of a dielectric stack covering at least in part a surface of the radial component of the radial bi-composite resonator. In use, an external magnetic field source is used to apply an external magnetic field to the radial bi-composite resonator.

In specific practical implementations, the waveguide circulator may be either an E-plane circulator or an H-plane circulator.

In some implementations, the use of one of more radial bi-composite resonators comprised of a radial component including a centrally disposed ferrite element and a concentrically disposed solid dielectric layer and of a dielectric stack covering at least in part a surface of the radial component as described above may allow for improved dissipation of energy absorbed by the ferrite to the body of the circulator. Such improved dissipation helps increase the average wave power level handling capability of the resonators and thus increases the average wave power level handling capability of the circulator as a whole.

In some specific practical implementations, the dielectric stack may cover either part or the entire top surface of the ferrite element of the radial component and may cover part or the entire top surface of the solid dielectric layer of the radial component.

The overall shape of the radial bi-composite resonator may vary between implementations. For example, the radial bi-composite resonator may have a disk shape, a triangular shape or any other suitable shape. In addition, the edge or edges defining the periphery of the radial bi-composite resonator may be a substantially sharp edge or edges or, alternatively, may be a rounded edge or rounded edges.

In addition, the specific shape of the ferrite element, solid dielectric layer and dielectric stack may vary from one implementation to the other. For example, in some specific implementations, the ferrite element may be a ferrite disk and the solid dielectric layer may be a dielectric ring shaped to surround the ferrite disk. In some other specific implementations, the ferrite element may have a triangular shape and the solid dielectric layer may have a complementary triangular inner surface for surrounding the periphery of the ferrite element. In both the above examples, the dielectric stack may be shaped to extend across a surface of the ferrite element and a surface of the solid dielectric layer.

In specific implementations, the radial bi-composite resonator may be positioned on one of the upper inner surface and the lower inner surface of the junction. In some specific implementations, the radial bi-composite resonator may be a first radial bi-composite resonator and the circulator may comprise a second radial bi-composite resonator positioned on the other one of the upper inner surface and the lower inner surface of the junction in a spaced-apart opposing relationship with the first radial bi-composite resonator. The second radial bi-composite resonator may be similarly configured to the first radial bi-composite resonator and may be comprised of a composite made of a radial component including a centrally disposed ferrite element and a solid dielectric layer disposed concentrically with and adjacent externally to the centrally disposed ferrite element and a dielectric stack covering at least in part a top surface of the radial component of the radial bi-composite resonator.

In specific implementations, the resonator may be positioned on a mounting pedestal formed on one of the upper inner surface and the lower inner surface of the junction. In some specific implementations, the radial bi-composite resonator may be a first radial bi-composite resonator and the mounting pedestal may be a first mounting pedestal, and the circulator may comprise a second radial bi-composite resonator positioned on a second mounting pedestal formed on the other one of the upper inner surface and the lower inner surface of the junction in a spaced-apart opposing relationship with the first radial bi-composite resonator.

In some non-limiting examples of implementations, the circulator proposed in the present document may be operated using an external magnetic field of a magnitude above magnetic resonance. Below magnetic resonance, there is a subsidiary resonance that absorbs RF energy, by the excitation of spin waves, which limits the maximum operating power level of the circulator. By operating above resonance, the impact on energy absorption by the ferrite due to an overlap between a subsidiary resonance and a main resonance associated with the resonators can be avoided. As a result, by using a circulator of the type suggested in the present application and operating it above resonance, a circulator having a higher peak power handling capability can be obtained.

In some implementations, a cooling module may be provided including circulation piping for circulating a coolant near the junction to assist in dissipating heat from the resonator, thus further increasing the average power handling capability of the circulator. In a non-limiting example in which a pulse-type RF field is applied to the circulator, heat is generated and is to be dissipated between the pulses. Typically in such cases the RF field would be applied during a short period of time, typically a couple of microseconds, and then turned off for a few milliseconds. For example, an 8 MW pulse of 5 microseconds on, and 5 milliseconds off will give an average power of about 8 kW. It is the average power level that will heat up the ferrites, and therefore needs to be dissipated to prevent the ferrites from overheating. By using a coolant, the rate at which the heat is dissipated can be increased thus increasing the average power handling capability of the circulator.

In accordance with another aspect, a waveguide circulator for use in a high power microwave circuit is provided. The waveguide circulator comprises at least three waveguide ports intersecting at a junction, wherein the junction has an upper inner surface and a lower inner surface positioned in an opposing relationship to said upper inner surface. The waveguide circulator also comprises a radial bi-composite resonator positioned within the junction, the resonator being comprised of a composite made of a centrally disposed ferrite element disposed so as to have one surface in contact with one of the lower inner surface and the upper inner surface of the junction. The composite is also made of a dielectric layer covering surfaces of the ferrite element other than the surface that is in contact with the one of the lower inner surface and the upper inner surface of the junction so that the ferrite element is encapsulated between the dielectric layer and the one of the lower inner surface and the upper inner surface of the junction. The waveguide circulator also comprises a magnetic field source for applying an external magnetic field to the radial bi-composite resonator.

The features of embodiments which are described in this disclosure are not mutually exclusive can be combined with one another. Elements of one embodiment can be utilized in the other embodiments without further mention. Other aspects and features of the present invention will become apparent to those ordinarily skilled in the art upon review of the following description of specific embodiments of the invention in conjunction with the accompanying drawings.

### BRIEF DESCRIPTION OF THE DRAWINGS

A detailed description of specific embodiments of the present invention is provided herein below with reference to the accompanying drawings in which:

FIG. 1A is a perspective view of an H-plane waveguide circulator in accordance with a typical configuration.

FIG. 1B is a side plan view of the H-plane waveguide circulator of FIG. 1A, exposing the interior of the waveguide circulator.

FIG. 1C is a cut-out perspective view of the H-plane waveguide circulator of FIG. 1A, exposing the interior of the waveguide circulator.

FIG. 2A is a perspective view of an E-plane waveguide circulator in accordance with a typical configuration.

FIG. 2B is a cut-out perspective view of the E-plane waveguide circulator of FIG. 2A, exposing a portion of the interior.

FIGS. 3A and 3B are respectively a side view and a top plan view of a full-height ferrite resonator in accordance with a specific conventional implementation.

FIGS. 4A, 4B and 4C are respectively a side view, a top plan view and a bottom plan view of an axial resonator in accordance with a specific conventional implementation.

FIGS. 5A and 5B are respectively a cross-sectional view and a top plan view of a radial composite resonator in accordance with a specific conventional implementation, wherein the cross-sectional view shown in FIG. 5A is a cross-section of the radial composite resonator shown in FIG. 5B taken along lines A-A.

FIGS. 6A and 6B are respectively a cross-sectional view and a cut-out perspective view of a radial bi-composite resonator in accordance with a specific implementation of the invention.

FIG. 7 illustrates a junction of an E-plane circulator in which two radial bi-composite resonators of the type shown in FIGS. 6A and 6B have been used in accordance with a specific implementation of the invention.

FIG. 8 is a cut-out perspective view of an E-plane waveguide circulator exposing an interior portion of the waveguide circulator, the E-plane waveguide circulator incorporating two radial bi-composite resonators of the type shown in FIGS. 6A and 6B in accordance with a specific example of implementation of the invention.

FIG. 9 is a cut-out perspective view of an H-plane waveguide circulator exposing an interior portion of the waveguide circulator, the H-plane waveguide circulator incorporating two radial bi-composite resonators of the type shown in FIGS. 6A and 6B in accordance with another specific example of implementation of the invention.

FIG. 10 shows experimental plots obtained using an implementation of an E-plane circulator of the type shown in FIG. 8 operating at 2.998 GHz, using a bi-composite resonator of FIGS. 6A and 6B.

FIGS. 11A and 11B are respectively a cross-sectional view and a cut-out perspective view of a radial bi-composite resonator in accordance with an alternative specific implementation of the invention.

FIG. 12 is a cut-out perspective view of an E-plane waveguide circulator exposing an interior portion of the waveguide circulator, the E-plane waveguide circulator incorporating two radial bi-composite resonators of the type shown in FIGS. 11A and 11B in accordance with a specific example of implementation of the invention.

FIG. 13 is a cut-out perspective view of an H-plane waveguide circulator exposing an interior portion of the waveguide circulator, the H-plane waveguide circulator incorporating two radial bi-composite resonators of the type shown in FIGS. 11A and 11B in accordance with another specific example of implementation of the invention.

FIG. 14A is a perspective view of a waveguide circulator in accordance with an alternative embodiment;

FIGS. 14B, 14C, 14D and 14E respectively are a front view, a top view, a side view and a rear view of the waveguide circulator of FIG. 14A;

FIGS. 15 and 16 respectively are a perspective view and a top view of a bottom portion of the waveguide circulator of FIG. 14A showing waveguide ports of the waveguide circulator meeting at a junction.

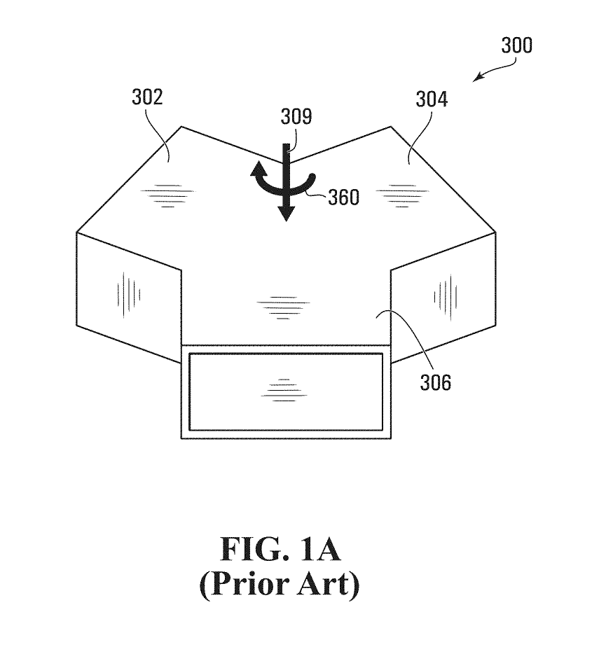

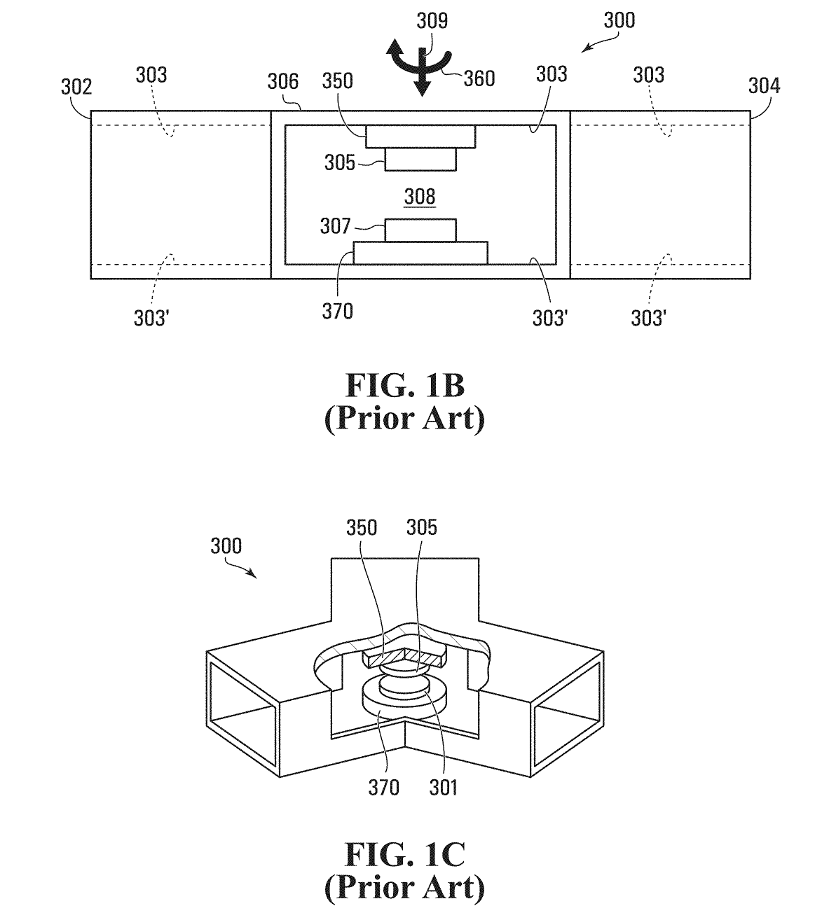

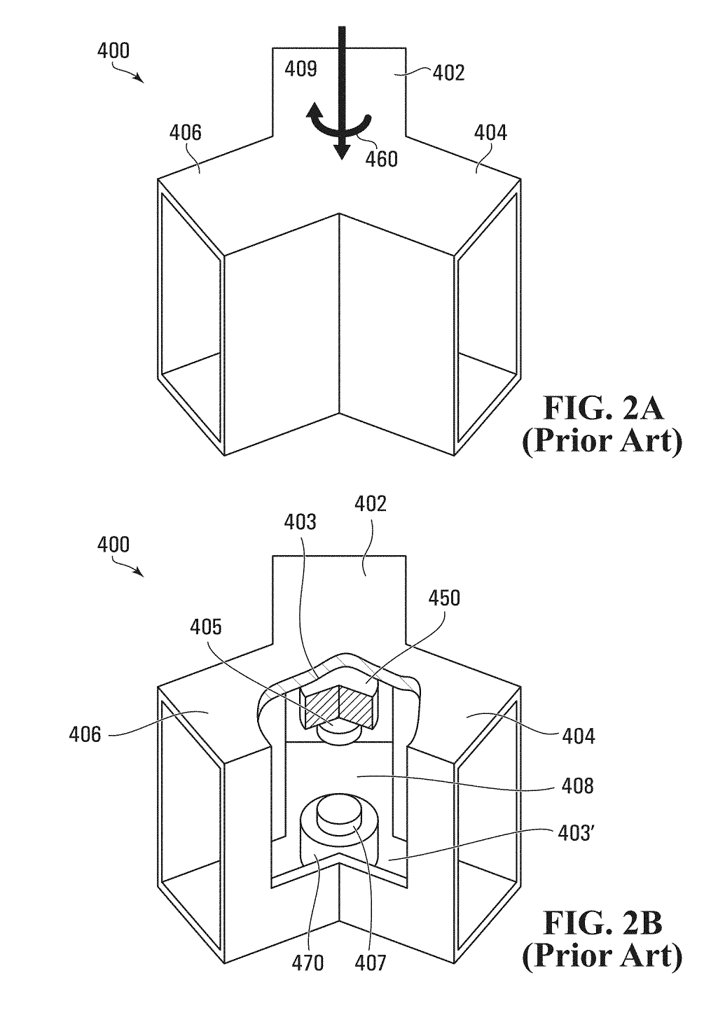

In the drawings, embodiments of the invention are illustrated by way of example. It is to be expressly understood that the description and drawings are only for the purpose of illustrating certain embodiments of the invention and are an aid for understanding. They are not intended to be a definition of the limits of the invention.

### DETAILED DESCRIPTION

For the purpose of clarity in the present description, it is to be understood that the meaning of above or below resonance is intended to refer to above or below magnetic resonance with respect to the magnetic field, not the operating frequency.

Specific examples of waveguide circulators will now be described to illustrate the manner in which the principles of the invention may be put into practice. Such waveguide circulators may have particular utility in satellite communications equipment encompassing both ground and space segments, as well as in the radar and medical fields.

Typical 3-port circulators are either H-plane or E-plane. While average power handling capability may be higher for H-plane circulator when compared to E-plane circulator, E-plane circulators can generally handle higher peak powers. The high peak power handling capability is provided in part by the presence of a larger gap between the resonators in an E-plane circulator when compared to the gap in an H-plane circulator. In addition, E-plane circulators tend to be more compact in comparison to their counterpart conventional H-plane circulators due to their geometry. Table 1 summarizes some differences between the use of E or H-plane configurations.

Table 1: Some Distinctions Between E and H-Plane Junction Circulators:

TABLE 1
Some distinctions between E and H-plane junction circulators:

| Property | H-Plane | E-Plane |
|---|---|---|
| Bandwidth | Very Large | Small to average |
| Return loss | Very good | Very good |
| Peak power handling | Good | Very good |
| Average power handling | Very good | Good |
| Compactness | Good | Very good |

The present invention may be used in connection with either E-plane circulators or H-plane circulators in order to improve the power dissipation characteristics of the ferrite elements of these devices, which may in turn improve the average power of the circulators. In addition, while examples presented in the present document show examples of E-plane and H-plane circulators having three (3) ports it is to be understood that the concepts presented herein may also apply to E-plane and H-plane circulators having any suitable number of ports.

Examples of embodiments of waveguide circulators for use in high power microwave circuits in accordance with specific practical examples of implementation will now be described with reference to the Figures.

While the waveguide circulators may have different configurations, as will be shown below, they are characterized in that they comprise one or more radial bi-composite resonators positioned within their junction. The radial bi-composite resonators comprised of a composite made of a centrally disposed ferrite element disposed so as to have one surface in contact with either a lower inner surface or an upper inner surface of the junction of the circulator. The composite is also made of a dielectric layer covering surface(s) of the ferrite element other than the surface that is in contact with the inner surface of the junction so that the ferrite element is at least partially, and in some implementations fully, encapsulated between the dielectric layer and the one of the lower inner surface and the upper inner surface of the junction.

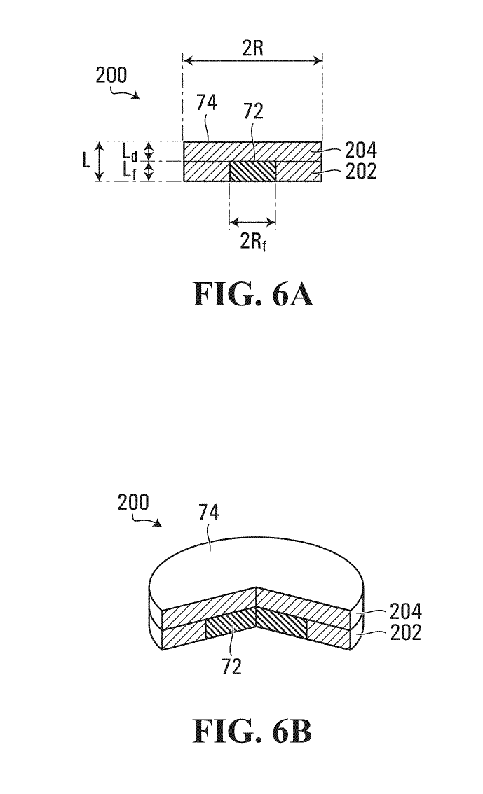

Examples of embodiments of radial bi-composite resonators will now been described with reference to the specific embodiments depicted in FIGS. 6A-B and 11A-B.

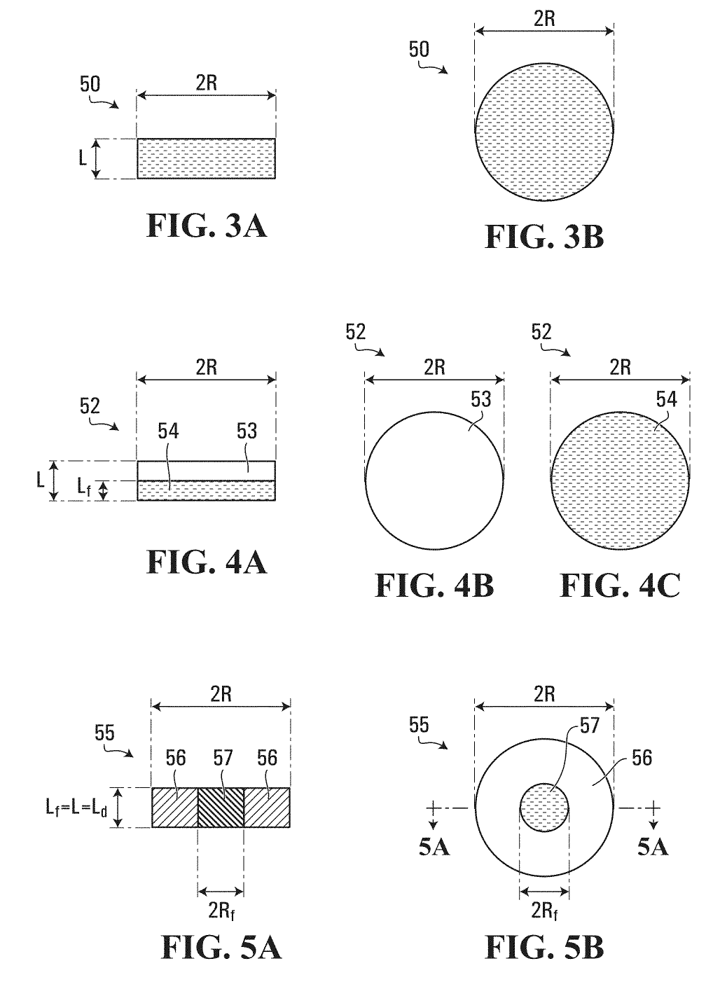

With reference to FIGS. 6A-B, a radial bi-composite resonator 200 is shown in accordance with a first specific implementation. In this configuration, the radial bi-composite resonator 200 is comprised of a composite made of a radial component including a centrally disposed ferrite element 72 and a solid dielectric layer 202 disposed concentrically with, and adjacent externally to, the centrally disposed ferrite element 72. The composite is also made of a dielectric stack 204 covering the upper surface of the ferrite element 72 and solid dielectric layer 202. The dielectric stack 204 is shaped to extend across the upper surface of the ferrite element 72 and the upper surface of the solid dielectric layer 202. In the example depicted, the ferrite element 72 is a ferrite disk and the solid dielectric layer is a dielectric ring 202 shaped to surround the ferrite disk. In the specific example shown, the dielectric ring 202 has a thickness L_{f}, an outer diameter 2R, inner diameter 2R_{f} and thermal conductivity σ_{d1} and surrounds the ferrite disk 72 of thickness L_{f}, diameter 2R_{f} and thermal conductivity σ_{f}. In this example, the dielectric stack 204 is shaped to extend across a surface of the ferrite element 72 and the surface of the solid dielectric layer 202 and has a diameter 2R, a thickness L_{d}=L−L_{f} and thermal conductivity σ_{d2}. The solid dielectric layer 202 and the dielectric stack 204 are chosen such that σ_{d1} and σ_{d2} are each >>σ_{f}, to reduce the thermal gradient over the ferrite element 72, and therefore improve the average power handling capability of the resonator 200 when compared to the power handling capability of the configuration shown in FIGS. 3A-B. In some implementations, the thermal conductivities σ_{d1}, and σ_{d2} may be equal to one another (for example when the solid dielectric layer 202 and the dielectric stack 204 are made of a same material). In alternative implementations, the thermal conductivities σ_{d1} and σ_{d2} may be different from one another (for example when the solid dielectric layer 202 and the dielectric stack 204 are made of a different material).

It will also be appreciated that, while the embodiment of the radial bi-composite resonator 200 depicted in FIGS. 6A and 6B shows that the solid dielectric layer 202 and the dielectric stack 204 are separate components that are connected to another in order to encapsulate in part the ferrite element 72 in the manner depicted in these figures, in alternative implementations (not shown in the Figures), the solid dielectric layer 202 and the dielectric stack 204 may be machined as a single component of height L and diameter 2R with a cut-out portion in the lower surface shaped to receive therein the ferrite element 72 of diameter 2R_{f} and height L_{f}.

In yet other embodiments, the solid dielectric layer 202 and the dielectric stack 204 may be separate components that are shaped and/or sized differently from what is depicted in FIGS. 6A and 6B. For example, in one alternative embodiment, (not shown in the Figures), the solid dielectric layer 202 may have a thickness L (instead of L_{f}), an outer diameter 2R and inner diameter 2R_{f} and the dielectric stack 204 may be shaped to extend across the upper surface of the ferrite element 72 only with a thickness L_{d}=L−L_{f} and a diameter 2R_{f}. In use, a fraction of the heat from the element 72 is radially transferred to the dielectric ring 202 and to the dielectric stack 204. In addition the reduced height of the ferrite diminishes the thermal gradient on the ferrite, and further improves heat dissipation. The improved heat dissipation is done at the expense of bandwidth. However, very high power amplifiers are often narrow band. In such cases, reducing the bandwidth of the circulator by using a radial bi-composite resonator 200 of the type depicted in FIGS. 6A and 6B would typically not be an issue.

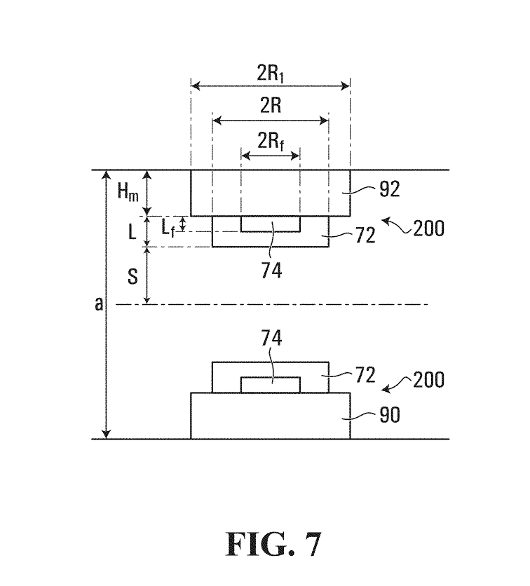

FIG. 7 shows the inside of a junction of an E-plane circulator including two (2) radial bi-composite resonators 200 of the type depicted in FIG. 6A-B. As shown, the ferrite element 72 of each radial bi-composite resonator 200 sits on a respective mounting pedestal 90 or 92. In the drawing, the upper inner wall of the junction and the lower inner wall of the junction are separated by a distance “a” and each pedestal as a height of H_{M}. The distance separating the upper portion of the resonators is:

2S=a−2H_{M}−2L

where L is the height of the resonator. In specific practical implementations, each of the mounting pedestals 90 or 92 is a metallic post or platform made from the same material as the body of the E-plane circulator and the connection between the mounting pedestals and the ferrite elements 72 allows the latter to dissipate a fraction of the heat. Another fraction of the heat from the ferrite elements 74 is radially transferred to the solid dielectric layer of the radial bi-composite resonators 200. The reduced height of the ferrite element 74 (compared to the configurations depicted in FIGS. 3A-C and 5A-C) diminishes the thermal gradient on the ferrite element 74, and may therefore improve heat dissipation characteristics. The person skilled in the art will appreciate that this increase in power handling capability is done at the expense of bandwidth since the bandwidth is related with the volumetric amount of ferrite in the radial bi-composite resonator 200. As such, implementations of resonators of the type shown in FIGS. 6A-B and 7 would be typically suitable for applications having relatively narrower bandwidth but higher power requirements.

It is however to be appreciated that in typical applications, very high power amplifiers are often narrow band. In such cases, reducing the bandwidth of the circulator by using a composite resonator would therefore not raise significant practical concerns.

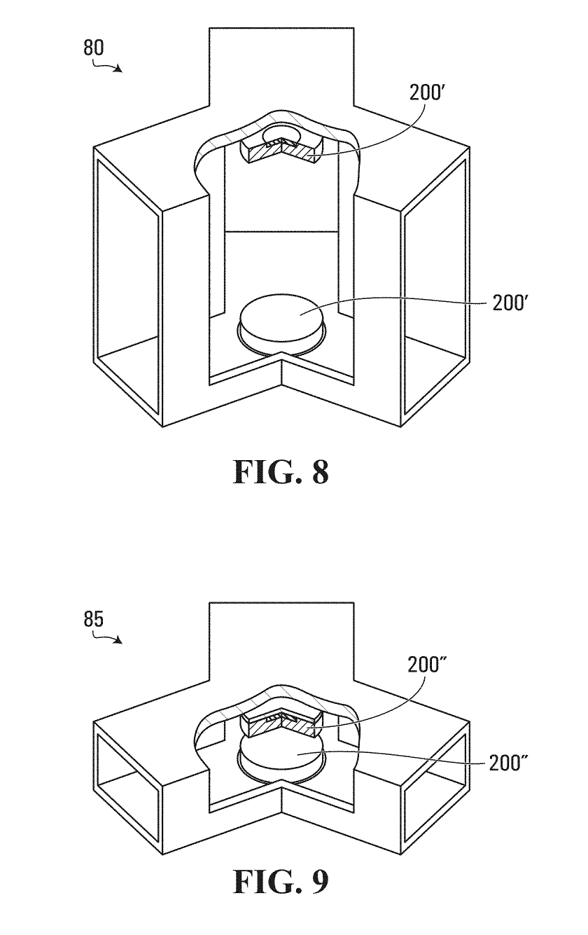

FIGS. 8 and 9 show circulators in which embodiments of the radial bi-composite resonator described in the present document have been incorporated. More specifically, FIG. 8 is a cut-out perspective view of an E-plane waveguide circulator 80 having three waveguide ports that meet at a common junction. In the embodiment shown, the three waveguide ports are evenly spaced at 120° angles in relation to each other. Although three evenly spaced waveguide ports are shown in FIG. 8, alternative implementations of waveguide circulators may include more or less than three waveguide ports, as well as waveguide ports that are not evenly spaced.

FIG. 8 exposes an interior portion of the common junction in which two radial bi-composite resonators 200′ 200′, analogous to the radial bi-composite resonator 200 described with reference to FIGS. 6A and 6B, in accordance with a specific example of implementation of the invention. The composite resonators 200′ are in a spaced-apart, opposing relationship, and are centrally disposed and arranged symmetrically with respect to the three waveguide ports. The specific dimensions of the radial bi-composite resonators 200′ will depend on the frequency characteristic that the E-plane waveguide circulator 80 is intended to operate under. The determination of the dimensions can be done using any suitable approach and will be readily apparent to the person skilled in the art in view of the present description.

FIG. 9 is a cut-out perspective view of an H-plane waveguide circulator 85 having three waveguide ports that meet at a common junction. The Figure exposes an interior portion of the common junction in which two radial bi-composite resonators 200″ 200″, analogous to the radial bi-composite resonator 200 described with reference to FIGS. 6A and 6B, in accordance with a specific example of implementation of the invention. The composite resonators 200″ are in a spaced-apart, opposing relationship, and are centrally disposed and arranged symmetrically with respect to the three waveguide ports. The specific dimensions of the radial bi-composite resonators 200″ will depend on the frequency characteristic that the H-plane waveguide circulator 85 is intended to operate under. The determination of the dimensions can be done using any suitable approach and will be readily apparent to the person skilled in the art in view of the present description.

In the specific non-limiting examples depicted in FIGS. 8 and 9, the radial bi-composite resonators 200′ and 200″ are shown mounted directly on the inner surfaces of the common junctions of the circulators 80 and 85 with no pedestal (or with pedestals of height H_{M}=0). Such configuration may improve thermal transfer between the ferrite elements of the radial bi-composite resonators 200′ and 200″ and the metallic housing of the circulators 80 and 85. In alternative implementations (not shown in the Figures), the radial bi-composite resonators may be affixed atop respective mounting pedestals of a waveguide circulator.

The radial bi-composite resonators 200′ 200″ may be fastened to the inner surface of the junction using any suitable adhesive or glue. In specific practical implementations, silicone-based adhesives may be used to affix the radial composite resonators 200′ 200″ to the inner surface of the junction. When the circulators including mounting pedestals 22 (pedestals of height H_{M}>0), these may be formed on respective ones of the upper and lower inner surfaces of the junctions. It will be appreciated that the mounting pedestals may be formed as integral parts of the upper and lower inner surfaces of the junction such that, in practice, the upper and lower inner surfaces of the junction are defined by the mounting pedestals. The mounting pedestals hold each of the respective radial composite resonators 200′ 200″ in place, and form an electrical wall by making contact with the radial bi-composite resonators. This arrangement provides a resonator with both a top and bottom electrical wall and a magnetic wall positioned at the midpoint between the two ferrite elements.

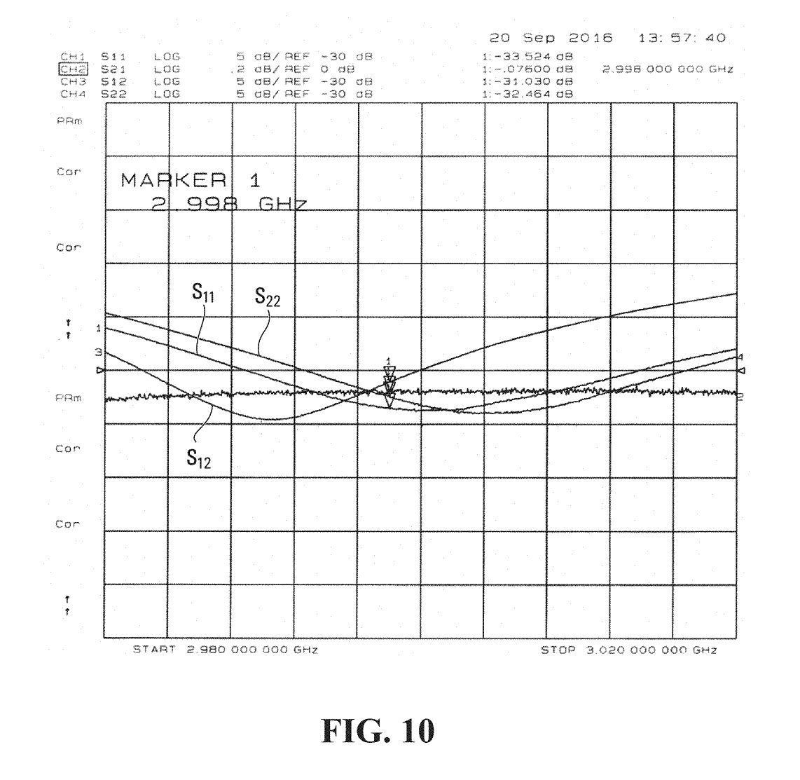

Experimental plots of an E-plane circulator of the type depicted in FIG. 8 and operating at 2.998 GHz is shown in FIG. 10. As can be observed, the frequency response of an E-plane circulator of the type depicted in FIG. 8 incorporating radial bi-composite resonators of the type described with reference to FIGS. 6A and 6B, is similar to the frequency response of an E-plane circulator incorporating resonators of the type depicted in FIGS. 5A-5B but with improved power handling capability. In the graph of FIG. 8. S₁₁ and S₂₂ are the input and output return losses (they are linked with the amount of power returning to the input and output ports), S₂₁ is the insertion loss (linked to the amount of power that reaches the output port), S₁₂ the isolation (linked to the amount of power that reaches the input port if we launch from the output port).

It is to be appreciated that, while the embodiments depicted in FIGS. 8 and 9 show two resonators 200′ 200″, alternative embodiments (not shown in the figures) may include a single resonator of the type described above, wherein the single resonator may be positioned on either the upper inner surface or the lower inner surface of the junction. For the purpose of simplicity, the present document will describe the embodiment in which the waveguide circulator includes pair of radial bi-composite resonators 200′ 200″.

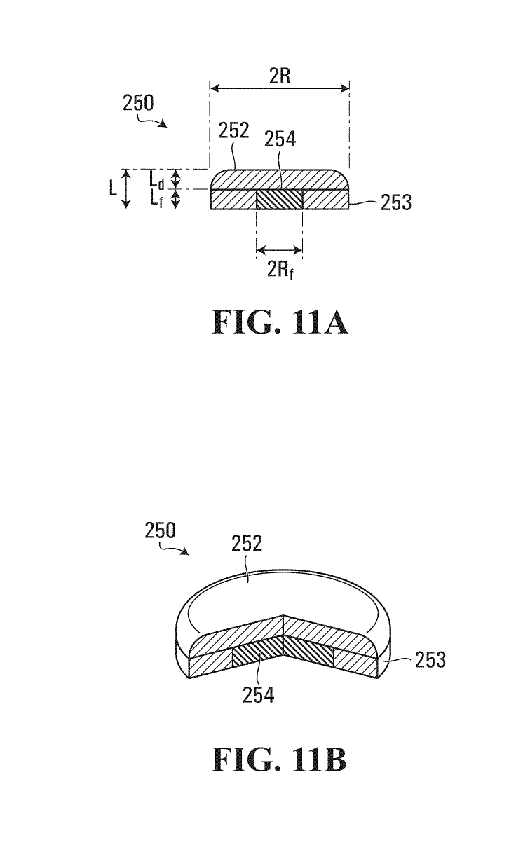

With reference to FIGS. 11A-B, a radial bi-composite resonator 250 is shown in accordance with a second specific implementation. In this configuration, the radial bi-composite resonator 250 is similar to the radial bi-composite resonator 200 described with reference to FIGS. 6A-B but has a periphery characterized by a rounded upper edge. Such rounded edge configuration may assist in reducing the occurrence of arcing and/or chipping of the resonator when the circulators in which they are incorporated operate at high peak power levels. As depicted, the radial bi-composite resonator 250 shown in FIGS. 11A-B is comprised of a composite made of a radial component including a centrally disposed ferrite element 254 (analogous to ferrite element 72 shown in FIGS. 6A-B) and a solid dielectric layer 253 (analogous to solid dielectric layer 202 of FIGS. 6A-B) disposed concentrically with, and adjacent externally to, the centrally disposed ferrite element 254. The composite is also made of a dielectric stack 252 (analogous to dielectric stack 204 of FIGS. 6A-B) covering the upper surface of the ferrite element 154 and solid dielectric layer 253. The dielectric stack 252 is shaped to extend across the upper surface of the ferrite element 254 and the upper surface of the solid dielectric layer 253. In the example depicted, the ferrite element 254 is a ferrite disk and the solid dielectric layer is a dielectric ring 253 shaped to surround the ferrite disk. In the specific example shown, the dielectric ring 253 has a thickness L_{f}, an outer diameter 2R, inner diameter 2R_{f} and thermal conductivity σ_{d1} and surrounds the ferrite disk 254 of thickness L_{f}, diameter 2R_{f} and thermal conductivity σ_{f}. In this example, the dielectric stack 252 is shaped to extend across a surface of the ferrite element 254 and the surface of the solid dielectric layer 253 and has a diameter 2R, a thickness L_{d}=L−L_{f} and thermal conductivity σ_{d2}. In the example depicted, the periphery of the dielectric stack 252 is characterized by a rounded edge.

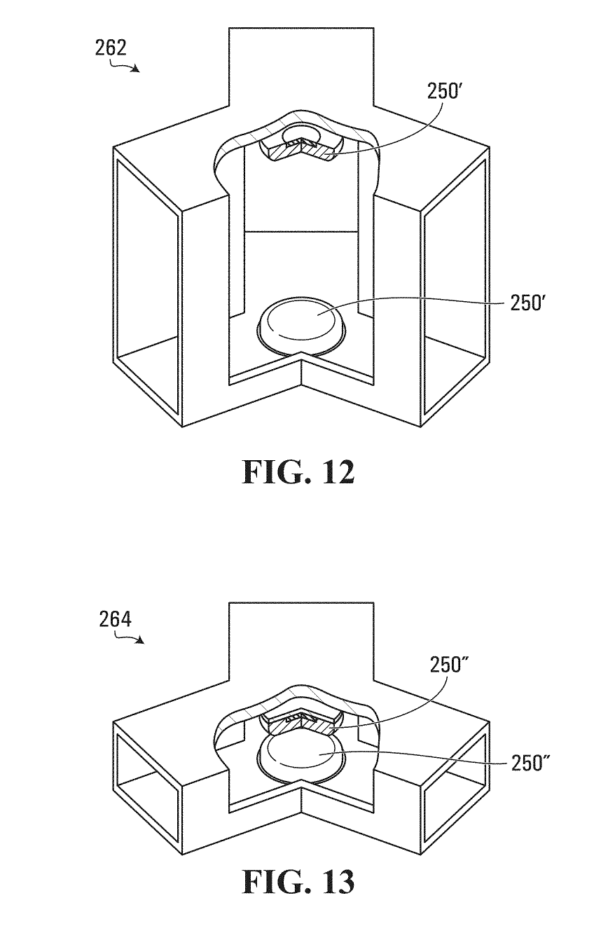

FIGS. 12 and 13 show circulators in which embodiments of the radial bi-composite resonator 250 described in the present document with reference to FIG. 11A-B have been incorporated. More specifically, FIG. 12 is a cut-out perspective view of an E-plane waveguide circulator 262 having three waveguide ports that meet at a common junction. The Figure exposes an interior portion of the common junction in which two radial hi-composite resonators 250′ 250′, analogous to the radial bi-composite resonator 250 described with reference to FIGS. 11A and 11B, in accordance with a specific example of implementation of the invention. The specific dimensions of the radial bi-composite resonators 250′ will depend on the frequency characteristic that the E-plane waveguide circulator 262 is intended to operate under. The determination of the dimensions can be done using any suitable approach and will be readily apparent to the person skilled in the art in view of the present description.

FIG. 13 is a cut-out perspective view of an H-plane waveguide circulator 264 having three waveguide ports that meet at a common junction. The Figure exposes an interior portion of the common junction in which two radial bi-composite resonators 250″ 250″, analogous to the radial bi-composite resonator 250 described with reference to FIGS. 11A and 11B, in accordance with a specific example of implementation of the invention. The specific dimensions of the radial bi-composite resonators 250″ will depend on the frequency characteristic that the H-plane waveguide circulator 264 is intended to operate under. The determination of the dimensions can be done using any suitable approach and will be readily apparent to the person skilled in the art in view of the present description.

In the specific non-limiting examples depicted in FIGS. 12 and 13, the radial bi-composite resonators 250′ and 250″ are shown mounted directly on the inner surfaces of the common junctions of the circulators 262 and 264 with no pedestal (or with pedestals of height H_{M}=0). Such configuration may improve thermal transfer between the ferrite elements of the radial bi-composite resonators 250′ and 250″ and the metallic housing of the circulators 262 and 264.

During operation, the radial composite resonators 200′ 200″ 250′ 250″ are subjected to the influence of an external magnetic field that is generated by a magnetic field source. The magnetic field source may consist of permanent magnets, which may be respectively positioned above and below the radial bi composite resonators 200′ 200″ 250′ 250″. Alternatively, the permanent magnets may be replaced by electromagnets in some implementations. The external magnetic field that is generated by the magnets is a uni-directional magnetic field such that wave energy entering each waveguide port will move in a clockwise or counter-clockwise direction towards its neighboring waveguide port. In this manner, wave energy is always propagated in a single direction. As such, the waveguide circulator is a non-reciprocal transmitter of electromagnetic wave energy propagating in the waveguide ports. By changing the direction of the magnetic field, it is possible for the wave energy to propagate in the opposite, clockwise, direction. However, regardless of the direction in which the wave energy is propagated, it can only ever travel in one direction at a time.

It will be appreciated that the specific dimensions and shapes of the radial composite resonators 200 and 250 described with reference to FIGS. 6A-B and 11A-B may vary significantly in different embodiments and will depend on multiple design choices that may be made by the person skilled in the art in view of the teachings of the present application.

For instance, while embodiments of the radial composite resonators 200 and 250 have been described in which the ferrite element 72 254 is a ferrite disk and in which the solid dielectric layer 202 253 is a dielectric ring shaped to surround the ferrite disk, it is to be appreciated that the radial composite resonators 200 and 250 in alternative implementations can be of a variety of shapes and/or sizes. For example, in some embodiments, the radial composite resonators can be of a triangular, hexagonal, pentagonal or any suitable arbitrary shape. In a specific implementation in which the ferrite element 72 254 has a triangular shape, the solid dielectric layer 202 253 may have a complementary triangular inner surface for surrounding a periphery of the triangular ferrite element and an outer peripheral surface of any suitable arbitrary shape. Similarly, the dielectric cap 204 252 may be shaped to complement the shape of the upper surface of the ferrite element and solid dielectric layer.

In addition, while in some of the embodiments depicted in the figures, the bi-composite resonator 200 has been shown with mounting pedestals 92 and 90 (for example in the form of a mounting post) having a height H_{M} (for example see FIG. 7), it is to be appreciated that in some alternative implementations, the mounting pedestals 92 and 90 may be omitted (or alternatively may be considered to have a height H_{M} equal to zero). In such implementations (for example as shown in FIGS. 8, 9, 12 and 13) the surfaces of the pedestals 92 and 90 would lie at the same levels as the lower and upper surfaces of the junction, which would in turn lie at the same levels at the base wall, an upper wall of the waveguide ports.

Alternate Configurations

While specific configurations of E-plane and H-plane circulators have been described with reference to waveguide circulators 80 85 262 and 264 (components of which were shown in FIGS. 8, 9, 12 and 13), it is to be appreciated that alternate embodiments of waveguide circulators of the type contemplated may be configured in many various alternate ways that will become apparent to the person skilled in the art in light of the present description.

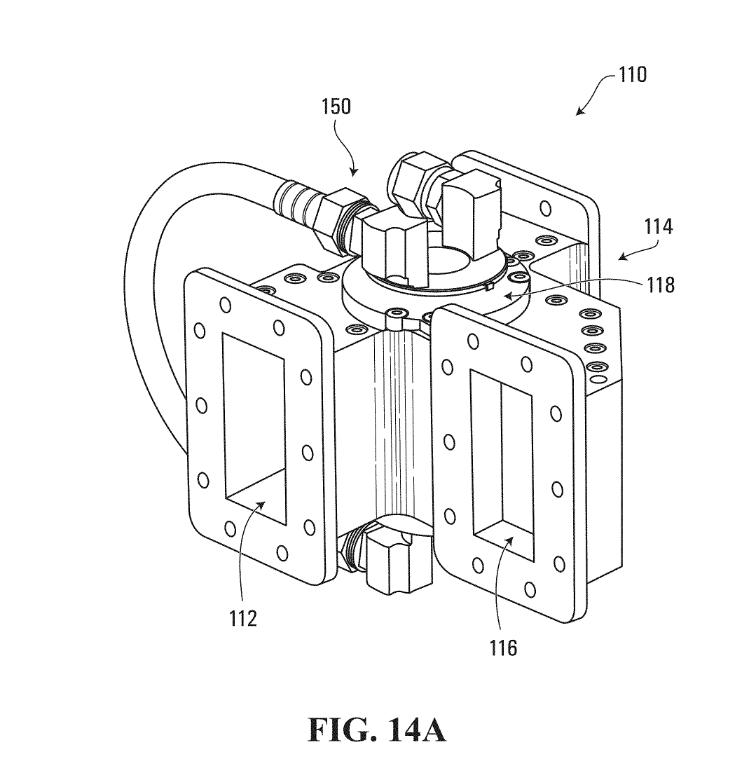

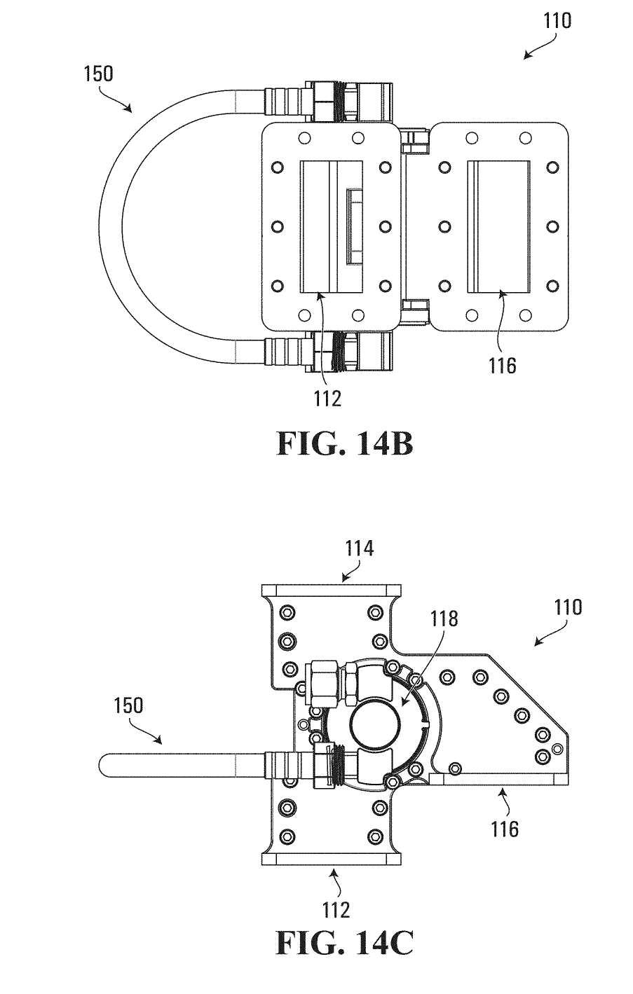

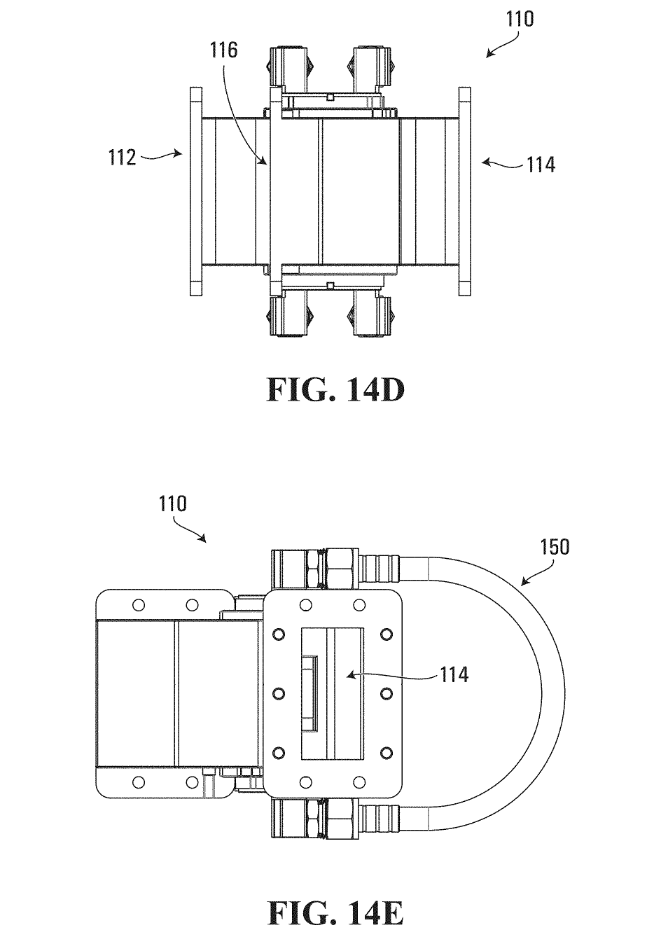

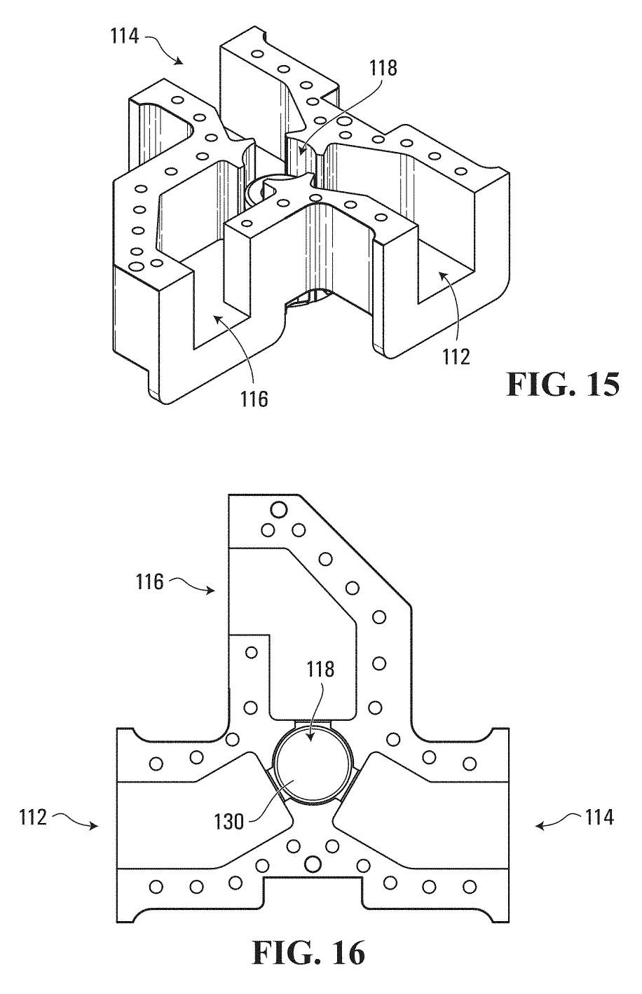

For example, an E-plane waveguide circulator 110 in accordance with another embodiment is shown in FIGS. 14A, 14B, 14C, 14D, 14E, 15 and 16. The waveguide circulator 110 similarly comprises a set of waveguide ports 112, 114 and 116 that meet at a junction 118 where a pair of radial composite resonator (one of which 130 is shown in FIG. 16), which may be implemented in a manner similar to the resonators 200 or 250 described above, are positioned. As can be observed, two of the ports 112 116 are oriented such that they are facing substantially the same direction which would allow circuitry connected to these ports to be positioned alongside one another. Such configuration may allow, in some cases, for a more compact layout of the connection circuits and/or termination elements, which in turn would assist in reducing the space required for a circuit incorporating the E-plane waveguide circulator 110. A pair of magnets positioned above and below respective ones of the radial composite resonators is configured to apply a magnetic field of a magnitude above resonance to the radial composite resonators.

In the embodiment shown in FIG. 14A, the waveguide circulator 110 also comprises a cooling module 150 configured to dissipate heat from the junction 118. More specifically, the cooling module 150 comprises circulation piping for circulating a coolant near the junction 118. This may assist in dissipating heat from the resonators at the junction 118 and increase the stability of the circulator 110. Such cooling modules are generally known in the art and thus will not be described further. A similar cooling module may also be used in the waveguide circulators 80 85 262 and 264 described above.

In alternative implementations, embodiments of the radial bi-composite resonators 200 and 250 may be used to replace the radial composite resonators in the circulators described international application serial no. PCT/CA2015/050481 filed May 27, 2015 and presently pending. The contents of the aforementioned application are incorporated herein by reference.

Manufacturing

In specific practical implementations, waveguide circulators 80 85 262 264 and 110 of the type described in the present document can be manufactured using any suitable manufacturing technique including molding, casting, or machining, among other possible manufacturing techniques. Generally speaking, the waveguide circulators 80 85 262 264 and 110 are made in two separate portions; namely a bottom portion and an upper portion, that are then coupled together in order to form the complete waveguide circulator 80 85 262 264 or 110. The bottom portion and the top portion can be coupled together via welding, bolts, rivets, or any other type of mechanical fastener known in the art. Alternatively, the top and bottom portion may be coupled together by a brazing process.

In accordance with a non-limiting example of implementation, the waveguide circulators 80 85 262 264 and 110 may be made of aluminum. However, it should be appreciated that the waveguide circulators 80 85 262 264 and 110 could be made of any suitable material, such as copper or brass, among other possibilities.

In addition while the waveguide ports of the circulators shown in the examples have a generally rectangular cross section, it should be appreciated that waveguide ports of other cross sections (such as square or circular) may also be contemplated in alternative implementations.

In the above description, only three ports have been shown and discussed in connection with the examples of waveguide circulators 80 85 262 264 and 110 described in the present document. It should however be appreciated that the concepts and features shown and described herein could be equally applied to T-junction circulators, four-port circulators, or circulators having any number of ports.

Waveguide circulators such as the waveguide circulators 80 85 262 264 and 110 described above may be used in a variety of domains. For example, radiotherapy devices used in the medical field to treat cancer or other diseases can use such waveguide circulators in circuit carrying high power RF energy to accelerate electrons or protons which are used to target specific cells in a patient's body (e.g., cancerous cells). In some alternate embodiments, the waveguide circulators 80 85 262 264 110 may be used as part of a satellite communications system. In yet other embodiments, the waveguide circulators 80 85 262 264 and 100 may be used as part of a radar antenna.

The foregoing is considered as illustrative only of the principles of the invention. Since numerous modifications and changes will become readily apparent to those skilled in the art in light of the present description, it is not desired to limit the invention to the exact examples and embodiments shown and described, and accordingly, suitable modifications and equivalents may be resorted to. It will be understood by those of skill in the art that throughout the present specification, the term “a” used before a term encompasses embodiments containing one or more to what the term refers. It will also be understood by those of skill in the art that throughout the present specification, the term “comprising”, which is synonymous with “including,” “containing,” or “characterized by,” is inclusive or open-ended and does not exclude additional, un-recited elements or method steps.

Unless otherwise defined, all technical and scientific terms used herein have the same meaning as commonly understood by one of ordinary skill in the art to which this invention pertains. In the case of conflict, the present document, including definitions will control.

Although the present invention has been described in considerable detail with reference to certain embodiments thereof, variations and refinements are possible and will become apparent to persons skilled in the art in light of the present description. The invention is defined more particularly by the attached claims.

What is claimed is:

1. A waveguide circulator for use in a high power microwave circuit, said waveguide circulator comprising:
a) at least three waveguide ports intersecting at a junction, wherein the junction has an upper inner surface and a lower inner surface positioned in an opposing relationship to said upper inner surface; and
b) a radial bi-composite resonator positioned within said junction, said radial bi-composite resonator being comprised of a composite made of:
i) a radial component including a centrally disposed ferrite element and a solid dielectric layer disposed concentrically with and adjacent externally to said centrally disposed ferrite element; and
ii) a dielectric stack covering at least in part a surface of the radial component of the radial bi-composite resonator;
c) a magnetic field source for applying an external magnetic field to said radial bi-composite resonator.

2. A waveguide circulator for use in a high power microwave circuit, said waveguide circulator comprising:
a) at least three waveguide ports intersecting at a junction, wherein the junction has an upper inner surface and a lower inner surface positioned in an opposing relationship to said upper inner surface; and
b) a radial bi-composite resonator positioned within said junction, said radial bi-composite resonator being comprised of a composite made of a:
i) a radial component including a centrally disposed ferrite element and a solid dielectric layer disposed concentrically with and adjacent externally to said centrally disposed ferrite element; and
ii) a dielectric stack covering at least in part a top surface of the radial component of the radial bi-composite resonator,
wherein in use, an external magnetic field source applies an external magnetic field to said radial bi-composite resonator.

3. The waveguide circulator defined in claim 2, wherein the dielectric stack covers the top surface of the ferrite element of the radial component.

4. The waveguide circulator defined in claim 3, wherein the dielectric stack covers a top surface of the solid dielectric layer of the radial component.

5. The waveguide circulator defined in claim 2, wherein the radial hi-composite resonator has a periphery characterized by a rounded edge.

6. The waveguide circulator defined in claim 2, wherein:
a) said ferrite element is a ferrite disk; and
b) said solid dielectric layer is a dielectric ring shaped to surround said ferrite disk.

7. The waveguide circulator defined in claim 2, wherein said ferrite element has a triangular shape and wherein said solid dielectric layer has a complementary triangular inner surface for surrounding the periphery of said ferrite element.

8. The waveguide circulator defined in claim 2, wherein the dielectric stack is shaped to extend across a surface of said ferrite element and a surface of said solid dielectric layer.

9. The waveguide circulator defined in claim 2, wherein said radial bi-composite resonator is positioned on a mounting pedestal formed on one of the upper inner surface and the lower inner surface of the junction.

10. The waveguide circulator defined in claim 9, wherein said radial hi-composite resonator is a first radial bi-composite resonator and wherein said mounting pedestal is a first mounting pedestal, said circulator comprising a second radial bi-composite resonator positioned on a second mounting pedestal formed on the other one of the upper inner surface and the lower inner surface of the junction in a spaced-apart opposing relationship with said first radial bi-composite resonator.

11. The waveguide circulator defined in claim 2, said radial bi-composite resonator is positioned on one of the upper inner surface and the lower inner surface of the junction.

12. The waveguide circulator defined in claim 11, wherein said radial bi-composite resonator is a first radial bi-composite resonator, said circulator comprising a second radial bi-composite resonator positioned on the other one of the upper inner surface and the lower inner surface of the junction in a spaced-apart opposing relationship with said first radial bi-composite resonator.

13. The waveguide circulator defined in claim 12, wherein said second radial bi-composite resonator comprised of a composite made of a radial component including a centrally disposed ferrite element and a solid dielectric layer disposed concentrically with and adjacent externally to said centrally disposed ferrite element and a dielectric stack covering at least in part a top surface of the radial component of the radial bi-composite resonator.

14. The waveguide circulator defined in claim 2, further comprising a cooling module including circulation piping for circulating a coolant near said junction to assist in dissipating heat from said radial bi-composite resonator.

15. The waveguide circulator defined in claim 2, wherein said magnetic field source includes an electromagnet.

16. The waveguide circulator defined in claim 2, wherein the waveguide circulator is an E-plane circulator.

17. The waveguide circulator defined in claim 2, wherein the waveguide circulator is an H-plane circulator.

18. A method of using the waveguide circulator of claim 2, the method comprising applying an external magnetic field having a magnitude greater than a magnetic resonance associated with the radial bi-composite resonator.

19. A radiotherapy device comprising the waveguide circulator of claim 2.

20. A radar antenna comprising the waveguide circulator of claim 2.

21. A waveguide circulator for use in a high power microwave circuit, said waveguide circulator comprising:
a) at least three waveguide ports intersecting at a junction, wherein the junction has an upper inner surface and a lower inner surface positioned in an opposing relationship to said upper inner surface; and
b) a radial bi-composite resonator positioned within said junction, said resonator being comprised of a composite made of:
i) a centrally disposed ferrite element disposed so as to have one surface in contact with one of the lower inner surface and the upper inner surface of the junction;
ii) a dielectric layer covering surfaces of the ferrite element other than the surface that is in contact with the one of the lower inner surface and the upper inner surface of the junction so that the ferrite element is encapsulated between the dielectric layer and the one of the lower inner surface and the upper inner surface of the junction;
c) a magnetic field source for applying an external magnetic field to said radial bi-composite resonator.
